(19) United States
(12) Patent Application Publication
(10) Pub. No.: US 2024/0312895 A1
(43) Pub. Date: Sep. 19, 2024

(54) POWER MODULE AND VEHICLE-MOUNTED POWER CIRCUIT

(71) Applicant: Huawei Digital Power Technologies Co., Ltd., Shenzhen (CN)

(72) Inventors: Huibin Chen, Shanghai (CN); Yutao Wang, Shanghai (CN); Haiyan Liu, Shenzhen (CN); Song Chen, Shanghai (CN); Zhonghua Yin, Dongguan (CN); Zhen Lv, Shanghai (CN); Zhaoyue Wang, Shanghai (CN); Qiliang Yang, Shanghai (CN)

(21) Appl. No.: 18/672,681

(22) Filed: May 23, 2024

Related U.S. Application Data
(63) Continuation of application No. PCT/CN2023/078978, filed on Mar. 1, 2023.

(30) Foreign Application Priority Data
Apr. 18, 2022 (CN) 202210406560.1

(51) Int. Cl. H01L 23/498; H01L 23/00; H01L 23/373

(52) U.S. Cl. CPC H01L 23/49838; H01L 23/3735; H01L 23/49811; H01L 24/26; H01L 24/32; H01L 24/33; H01L 2224/26175; H01L 2224/32225; H01L 2224/32245; H01L 2224/33181

(57) ABSTRACT

A power module is provided that may include a first metal-clad substrate, a chip located on a side of the first metal-clad substrate, and first solder located between the first metal-clad substrate and the chip. A first metal layer is disposed on a surface that is of the first metal-clad substrate and that faces the chip, and the first metal layer includes a groove and a blocking part. A first thickness of the first metal layer is less than a second thickness. The first thickness is a thickness of at least a part of an area in the blocking part, and the second thickness is a thickness of the first metal layer in an area other than the groove and the blocking part. The blocking part is located between the chip and the adjacent groove, and is configured to prevent the first solder from overflowing into the groove.

### CROSS-REFERENCE TO RELATED APPLICATIONS

This application is a continuation of International Application No. PCT/CN2023/078978, filed on Mar. 1, 2023, which claims priority to Chinese Patent Application No. 202210406560.1, filed on Apr. 18, 2022. The disclosures of the aforementioned applications are hereby incorporated by reference in their entireties.

### TECHNICAL FIELD

This application relates to the field of power electronics technologies, and in particular, to a power module and a vehicle-mounted power circuit.

### BACKGROUND

With development of power electronics technologies, a power module has attracted increasing attention. The power module may include a copper-clad substrate and a chip. A copper layer of the copper-clad substrate includes a groove for forming a line. As power density of a power component continuously increases, an internal structure of the power module becomes more compact, so that a distance between the chip and an edge of the groove is increasingly small.

Inside the power module, the chip is usually interconnected with the copper-clad substrate through welding with solder. In a high-temperature welding process between the chip and the copper-clad substrate, heat may be transferred to the copper layer of the copper-clad substrate through the solder, and the copper-clad substrate inevitably undergoes warpage deformation. Deformation amounts of different modules vary slightly. As a result, warpage between the chip and the copper-clad substrate, a thickness of the solder, a distance between the solder and the edge of the groove, and the like are difficult to accurately control, and the edge of the groove near the chip bears large stress. To ensure sufficient solder, an amount of solder is slightly excessive. Because the distance between the chip and the adjacent groove is close, the solder easily overflows into a gap between the chip and the edge of the groove, and stress concentration is easy to occur on the edge of the groove, resulting in separation of the copper layer. As a result, reliability of the power module is poor.

### SUMMARY

This application provides a power module and a vehicle-mounted power circuit, to resolve poor reliability of the power module caused by a case in which solder in the power module easily overflows into a gap between a chip and an edge of a groove.

According to a first aspect, an embodiment of this application provides a power module. The power module provided in this embodiment of this application may include a first metal-clad substrate, a chip located on a side of the first metal-clad substrate, and first solder located between the first metal-clad substrate and the chip. A first metal layer is disposed on a surface that is of the first metal-clad substrate and that faces the chip, and the first metal layer may include a groove that penetrates the first metal layer in a thickness direction, and a blocking part. A first thickness of the first metal layer is less than a second thickness. The first thickness is a thickness of at least a part of an area in the blocking part, and the second thickness is a thickness of the first metal layer in an area other than the groove and the blocking part. The blocking part is located between the chip and the adjacent groove, and is configured to prevent the first solder from overflowing into the groove when the chip is welded to the first metal-clad substrate with the first solder.

In the power module provided in this embodiment of this application, the blocking part is disposed at the first metal layer of the first metal-clad substrate, and the blocking part is located between the chip and the adjacent groove. When the chip is welded to the first metal-clad substrate with the first solder, the blocking part can prevent the first solder from overflowing into the groove, to prevent the first solder from overflowing into a gap between the chip and an edge of the groove. This can further prevent the first metal layer from being separated due to stress concentration on the edge of the groove, and improve reliability of the power module. For example, a yield rate of the power module can be improved by at least 5%. In addition, the blocking part is a physical structure at the first metal layer. A material of the first metal layer does not need to be changed, and another material does not need to be added. Therefore, the blocking part has better effect of preventing overflow of the first solder and product reliability is high.

In this embodiment of this application, the first metal-clad substrate may include: a first substrate, the first metal layer located on a side that is of the first substrate and that faces the chip, and a second metal layer located on a side that is of the first substrate and that is away from the chip. The first metal layer and the second metal layer are disposed on two sides of the first substrate, so that the first metal-clad substrate has good heat dissipation performance, and the chip can dissipate heat by using the first metal-clad substrate. The groove at the first metal layer penetrates the first metal layer in the thickness direction. In this way, a line may be formed at the first metal layer by disposing the groove. In a specific implementation, in addition to a position adjacent to the chip, the groove may alternatively be disposed at another position, and the groove may be disposed based on a specific layout of the line. A material of the first substrate may be ceramic. Because the first solder is not wetted with a ceramic material, the first solder does not flow into the groove, to prevent the first solder from affecting a line layout of the first metal layer. For example, materials of the first metal layer and the second metal layer may be copper. Certainly, the first metal layer and the second metal layer may alternatively use other materials. This is not limited herein. In a specific implementation, the first metal-clad substrate may be direct bond copper (DBC), active metal brazed copper (AMB, for example, Al₂O₃-AMB, Si₃N₄-AMB, or AlN-AMB), an insulated metal substrate (IMS), or the like. This is not limited herein.

In this embodiment of this application, the chip is interconnected with the first metal-clad substrate by using the first solder, and the chip is welded to the first metal-clad substrate with the first solder. In a welding process, if an amount of the first solder is less than an actually demanded amount, in other words, the amount of the first solder is low, disadvantages such as insufficient solder between the chip and the first metal-clad substrate and a hollow hole on solder may be caused, and heat dissipation performance of the power module is greatly affected. Therefore, in this embodiment of this application, to ensure sufficient solder, the amount of the first solder is slightly greater than the actual amount, in other words, the amount of the first solder is slightly large. In a possible implementation, a material of the first solder may be tin. Certainly, the first solder may alternatively use another material. This is not limited herein.

Because an internal structure of the power module is compact, a distance between the chip and the adjacent groove is close. To prevent the first solder from overflowing into the groove, in this embodiment of this application, the blocking part is disposed between the chip and the adjacent groove. In this way, in a welding process, the blocking part can prevent the first solder from overflowing into the groove, to prevent the first solder from overflowing into the gap between the chip and the edge of the groove. This prevents the first metal layer from being separated due to stress concentration on the edge of the groove, and improves reliability of the power module. In addition, the blocking part does not penetrate the first metal layer. Therefore, disposing the blocking part does not affect the line layout of the first metal layer.

In a specific implementation, adjacent grooves may be disposed on one side, two sides, or three sides of the chip, and may be disposed based on an actual layout of the line. Positions of the grooves are not limited herein. For another side, of the chip, on which no adjacent groove is disposed, overflow of the first solder does not affect stress and the line layout. Therefore, no blocking part may be disposed on the another side, of the chip, on which no adjacent groove is disposed. When a specific structure of the blocking part is disposed, the blocking part may be disposed as a continuous or local structure, or the blocking part may be disposed as a discrete point shape or a discrete line shape.

In some embodiments of this application, the power module may further include a second metal-clad substrate disposed opposite to the first metal-clad substrate, and an interconnection column located between the first metal-clad substrate and the second metal-clad substrate. The chip is located between the first metal-clad substrate and the interconnection column.

Similar to the first metal-clad substrate, the second metal-clad substrate may include a second substrate, a third metal layer located on a side that is of the second substrate and that faces the chip, and a fourth metal layer located on a side that is of the second substrate and that is away from the chip. The third metal layer and the fourth metal layer are disposed on two sides of the second substrate, so that the second metal-clad substrate has good heat dissipation performance, and the chip can dissipate heat by using the second metal-clad substrate. A material of the second substrate may be ceramic, and materials of the third metal layer and the fourth metal layer may be copper. Certainly, the second substrate, the third metal layer, and the fourth metal layer may alternatively use other materials. This is not limited herein. In a specific implementation, the second metal-clad substrate may be direct bond copper (DBC), active metal brazed copper (AMB, for example, Al₂O₃-AMB, Si₃N₄-AMB, or AlN-AMB), an insulated metal substrate (IMS), or the like. This is not limited herein.

The interconnection column is disposed between the chip and the second metal-clad substrate. The interconnection column has good conductivity and thermal conductivity. For example, the interconnection column may be made of metal, alloy, or a composite material. The interconnection column may perform functions of mechanical connection, electrical connection, and heat conduction, so that the chip may be electrically connected to the second metal-clad substrate, and the chip can dissipate heat by using the second metal-clad substrate. In this way, metal-clad substrates are disposed on two sides of the chip, so that heat generated inside the power module can be discharged from a direction of the first metal-clad substrate and a direction of the second metal-clad substrate, thereby improving heat dissipation performance of the power module.

In a specific implementation, second solder may be disposed between the chip and the interconnection column, and third solder may be disposed between the interconnection column and the second metal-clad substrate, to implement an electrical connection between the chip and the interconnection column, and implement an electrical connection between the interconnection column and the second metal-clad substrate. In a specific implementation, a material that is not wetted with the second solder may be disposed on a surface that is of the chip and that corresponds to a periphery of the interconnection column, to define a position of the second solder. In this way, when the chip is welded to the interconnection column, the second solder can be prevented from spreading to the periphery, and the second solder is prevented from affecting performance of the chip. In a specific implementation, a groove may be disposed at the third metal layer to form a line at the third metal layer. If wiring space of the third metal layer is large, a distance between the interconnection column and a surrounding groove may be long, and the third solder does not overflow into an edge of the groove, and does not affect stress and a line layout of the third metal layer. If the wiring space of the third metal layer is small, the distance between the interconnection column and the surrounding groove may be close, and a blocking part may alternatively be disposed between the interconnection column and the groove of the third metal layer, to prevent the third solder from overflowing into an edge of the groove adjacent to the interconnection column. In this embodiment of this application, for a manner of disposing the blocking part at the third metal layer, refer to the blocking part at the first metal layer. Details are not described herein again.

In some embodiments of this application, the blocking part may include at least one recess structure that is recessed towards a first direction. The first direction is a direction in which the chip points to the first metal-clad substrate. By disposing the recess structure, surface tension of the first solder can be used to prevent flow of the first solder, and the recess structure has a specific volume, and overflowed first solder can flow into the recess structure, to buffer the overflowed first solder and prevent the first solder from overflowing into the edge of the groove, to prevent the first solder from overflowing into the groove.

In a manufacturing process of the power module, the recess structure may be formed by using a machining or etching method. In a specific implementation, a depth of the recess structure may be 25% to 75% of the second thickness of the first metal layer. In this way, the recess structure does not penetrate the first metal layer, and the line layout of the first metal layer is not affected. For example, the depth of the recess structure may be 30%, 50%, or 70% of the second thickness, and may be set based on an actual requirement. A specific value of the depth of the recess structure is not limited herein. Certainly, in some cases, the depth of the recess structure may alternatively be less than 25% of the second thickness or greater than 75% of the second thickness, provided that the recess structure does not penetrate the first metal layer.

In a possible implementation, the blocking part may include one recess structure. The recess structure extends along a second direction, and the second direction is an extension direction of a side that is of the chip and that is adjacent to the blocking part. In other words, the recess structure is a strip structure extending along the second direction. In a specific implementation, a length of the recess structure may be set to be greater than or equal to a length of the side of the corresponding chip, and a width of the recess structure may be set based on a size of space between the corresponding chip and the groove.

In another possible implementation, the blocking part may include a plurality of recess structures. The plurality of recess structures in the blocking part are arranged in at least one row, an arrangement direction of the recess structures is a second direction, and the second direction is an extension direction of a side that is of the chip and that is adjacent to the blocking part. In other words, the blocking part is a strip structure formed by arranging the plurality of recess structures. In a specific implementation, a total length of the plurality of recess structures in the blocking part may be set to be greater than or equal to a length of the side of the corresponding chip, and a quantity of recess structures may be set based on a length required by the blocking part. The width of the recess structure may be set based on a size of space between a corresponding chip and the groove. In actual application, a gap between adjacent recess structures may be set to be small, to prevent the first solder from overflowing through the gap between adjacent recess structures. When the recess structure is disposed, the recess structure may be circular, square, oval, or the like. A shape of the recess structure is not limited herein.

In some other embodiments of this application, the blocking part may include at least one step-shaped structure, and each step-shaped structure includes at least one step. In a specific implementation, the step-shaped structure may include one, two, three, or more steps. This is not limited herein. The step-shaped structure is disposed, steps in the step-shaped structure have a height difference, and a flow path of the first solder can be extended. The surface tension of the first solder can be utilized, so that the first solder flows to an edge of the step-shaped structure and stops, and the first solder is prevented from overflowing into the edge of the groove, to prevent the first solder from flowing into the groove.

In a manufacturing process of the power module, the step-shaped structure may be formed by using a machining or etching method. In a specific implementation, a thickness of the step-shaped structure may be 25% to 75% of the second thickness of the first metal layer. In this way, the step-shaped structure does not penetrate the first metal layer, and the line layout of the first metal layer is not affected. For example, the thickness of the step-shaped structure may be 30%, 50%, or 70% of the second thickness, and may be set based on an actual requirement. A specific value of the thickness of the step-shaped structure is not limited herein. Certainly, in some cases, the thickness of the step-shaped structure may alternatively be less than 25% of the second thickness or greater than 75% of the second thickness d2, provided that the thickness of the step-shaped structure does not penetrate the first metal layer.

In a possible implementation, the blocking part may include one step-shaped structure. The step-shaped structure extends along a second direction, and the second direction is an extension direction of a side that is of the chip and that is adjacent to the blocking part. In other words, the step-shaped structure is a strip structure extending along the second direction. In a specific implementation, a length of the step-shaped structure may be set to be greater than or equal to a length of the side of the corresponding chip, and a width of the step-shaped structure may be set based on a size of space between the corresponding chip and the groove.

In another possible implementation, the blocking part may include a plurality of step-shaped structures, the plurality of step-shaped structures in the blocking part are arranged in at least one row, an arrangement direction of the step-shaped structures is a second direction, and the second direction is an extension direction of a side that is of the chip and that is adjacent to the blocking part. In other words, the blocking part is a strip structure formed by arranging the plurality of step-shaped structures. In a specific implementation, a total length of the plurality of step-shaped structures in the blocking part may be set to be greater than or equal to a length of the side of the corresponding chip, and a quantity of step-shaped structures may be set based on a length required by the blocking part. A width of the step-shaped structure may be set based on a size of space between the corresponding chip and the groove. In actual application, a gap between adjacent step-shaped structures may be set to be small, to prevent the first solder from overflowing through the gap between the adjacent step-shaped structures.

According to a second aspect, an embodiment of this application further provides a vehicle-mounted power circuit. The vehicle-mounted power circuit may include any one of the foregoing power modules and a circuit board. The circuit board is electrically connected to the power module, and the vehicle-mounted power circuit is located in a vehicle-mounted charger or a vehicle-mounted inverter, and is configured to provide a power conversion function for an electric vehicle. In the foregoing power module, a blocking part is disposed at a first metal layer, to prevent first solder from overflowing into a gap between a chip and an edge of a groove. This can further prevent the first metal layer from being separated due to stress concentration on the edge of the groove, and improve reliability of the power module. Therefore, reliability of the vehicle-mounted power circuit including the power module is also high. A problem-resolving principle of the vehicle-mounted power circuit is similar to that of the foregoing power module. Therefore, for implementation of the vehicle-mounted power circuit, refer to the implementation of the foregoing power module. Repeated parts are not described again.

### BRIEF DESCRIPTION OF THE DRAWINGS

FIG. 1 is a schematic diagram of a cross-sectional structure of a power module according to an embodiment of this application;

FIG. 2 is a schematic diagram of a top-view structure of the power module shown in FIG. 1;

FIG. 3 is another schematic diagram of a top-view structure of the power module shown in FIG. 1;

FIG. 4 is another schematic diagram of a cross-sectional structure of a power module according to an embodiment of this application;

FIG. 5 is a schematic diagram of a top-view structure of the power module shown in FIG. 4; and

FIG. 6 is another schematic diagram of a top-view structure of the power module shown in FIG. 4.

### REFERENCE NUMERALS

11: first metal-clad substrate; 111: first substrate; 112: first metal layer; 113: second metal layer; 12: chip; 13: first solder; 14: second metal-clad substrate; 141: second substrate; 142: third metal layer; 143: fourth metal layer; 15: interconnection column; 16: second solder; 17: third solder; T: blocking part; t1: recess structure; t2: step-shaped structure; U: groove; F1: first direction; and F2: second direction.

### DETAILED DESCRIPTION OF ILLUSTRATIVE EMBODIMENTS

To make objectives, technical solutions, and advantages of this application clearer, the following further describes this application in detail with reference to accompanying drawings.

It should be noted that same reference signs in the accompanying drawings of this application represent same or similar structures, and therefore repeated descriptions thereof are omitted. Words for expressing positions and directions in this application are described by using the accompanying drawings as examples. However, changes may be made as required, and all changes shall fall within the protection scope of this application. The accompanying drawings in this application are merely used to show a relative position relationship, and do not represent a true scale.

Embodiments of this application provide a power module and a vehicle-mounted power circuit. The power module is a semiconductor apparatus that converts a voltage, a current, a frequency, and the like of a power supply. The power module may be used in the vehicle-mounted power circuit, and the vehicle-mounted power circuit may provide a power conversion function for an electric vehicle.

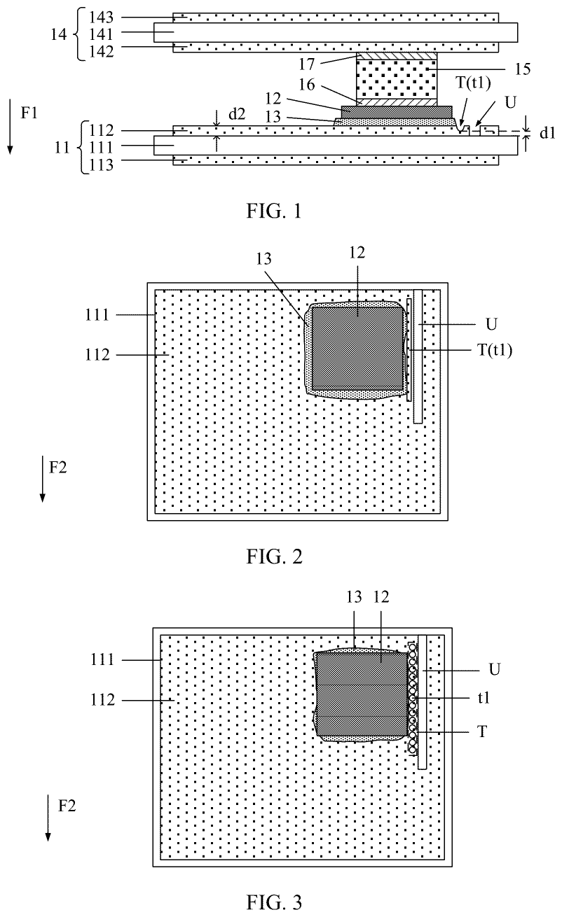

FIG. 1 is a schematic diagram of a cross-sectional structure of a power module according to an embodiment of this application. As shown in FIG. 1, the power module provided in embodiments of this application may include a first metal-clad substrate 11, a chip 12 located on a side of the first metal-clad substrate 11, and first solder 13 located between the first metal-clad substrate 11 and the chip 12. A first metal layer 112 is disposed on a surface that is of the first metal-clad substrate 11 and that faces the chip 12, and the first metal layer 112 may include a groove U that penetrates the first metal layer 112 in a thickness direction, and a blocking part T. A first thickness d1 of the first metal layer 112 is less than a second thickness d2. The first thickness d1 is a thickness of at least a part of an area in the blocking part T, and the second thickness d2 is a thickness of the first metal layer 112 in an area other than the groove U and the blocking part T. The blocking part T is located between the chip 12 and the adjacent groove U, and is configured to prevent the first solder 13 from overflowing into the groove U when the chip 12 is welded to the first metal-clad substrate 11 with the first solder 13.

In the power module provided in embodiments of this application, the blocking part is disposed at the first metal layer of the first metal-clad substrate, and the blocking part is located between the chip and the adjacent groove. When the chip is welded to the first metal-clad substrate with the first solder, the blocking part can prevent the first solder from overflowing into the groove, to prevent the first solder from overflowing into a gap between the chip and an edge of the groove. This can further prevent the first metal layer from being separated due to stress concentration on the edge of the groove, and improve reliability of the power module. For example, a yield rate of the power module can be improved by at least 5%. In addition, the blocking part is a physical structure at the first metal layer. A material of the first metal layer does not need to be changed, and another material does not need to be added. Therefore, the blocking part has better effect of preventing overflow of the first solder and product reliability is high.

In this embodiment of this application, the first metal-clad substrate 11 may include: a first substrate 111, the first metal layer 112 located on a side that is of the first substrate 111 and that faces the chip 12, and a second metal layer 113 located on a side that is of the first substrate 111 and that is away from the chip 12. The first metal layer 112 and the second metal layer 113 are disposed on the two sides of the first substrate 111, so that the first metal-clad substrate 11 has good heat dissipation performance, and the chip 12 can dissipate heat by using the first metal-clad substrate 11. The groove U in the first metal layer 112 penetrates the first metal layer 112 in the thickness direction. In this way, a line may be formed at the first metal layer 112 by disposing the groove U. In a specific implementation, in addition to a position adjacent to the chip 12, the groove U may alternatively be disposed at another position, and the groove U may be disposed based on a specific layout of the line. A material of the first substrate 111 may be ceramic. Because the first solder 13 is not wetted with a ceramic material, the first solder 13 does not flow into the groove U, to prevent the first solder 13 from affecting a line layout of the first metal layer 112. For example, materials of the first metal layer 112 and the second metal layer 113 may be copper. Certainly, the first metal layer 112 and the second metal layer 113 may alternatively use other materials. This is not limited herein. In a specific implementation, the first metal-clad substrate 11 may be direct bond copper (DBC), active metal brazed copper (AMB, for example, Al₂O₃-AMB, Si₃N₄-AMB, or AlN-AMB), an insulated metal substrate (IMS), or the like. This is not limited herein.

FIG. 2 is a schematic diagram of a top-view structure of the power module shown in FIG. 1. With reference to FIG. 1 and FIG. 2, the chip 12 is interconnected with the first metal-clad substrate 11 by using the first solder 13, and the chip 12 may be welded to the first metal-clad substrate 11 with the first solder 13. In a welding process, if an amount of the first solder 13 is less than an actually demanded amount, in other words, the amount of the first solder 13 is low, disadvantages such as insufficient solder between the chip 12 and the first metal-clad substrate 11 and a hollow hole on solder may be caused, and heat dissipation performance of the power module is greatly affected. Therefore, in this embodiment of this application, to ensure sufficient solder, the amount of the first solder 13 is slightly greater than the actual amount, in other words, the amount of the first solder 13 is slightly large. In a possible implementation, a material of the first solder 13 may be tin. Certainly, the first solder 13 may alternatively use another material. This is not limited herein.

Still refer to FIG. 1 and FIG. 2. Because an internal structure of the power module is compact, a distance between the chip 12 and the adjacent groove U is close. To prevent the first solder 13 from overflowing into the groove U, in this embodiment of this application, the blocking part Tis disposed between the chip 12 and the adjacent groove U. In this way, in a welding process, the blocking part T can prevent the first solder 13 from overflowing into the groove U, to prevent the first solder 13 from overflowing into the gap between the chip 12 and the edge of the groove U. This prevents the first metal layer 112 from being separated due to stress concentration on the edge of the groove U, and improves reliability of the power module. In addition, the blocking part T does not penetrate the first metal layer 112. Therefore, disposing the blocking part T does not affect the line layout of the first metal layer 112.

In FIG. 2, an example in which the adjacent groove U is disposed on a side of the chip 12 is used for illustration. For another side, of the chip 12, on which no adjacent groove U is disposed, overflow of the first solder 13 does not affect stress and the line layout. Therefore, no blocking part may be disposed on the another side, of the chip 12, on which no adjacent groove U is disposed. In a specific implementation, adjacent grooves U may alternatively be disposed on two sides or three sides of the chip 12, and may be disposed based on an actual layout of the line. Positions of the grooves U are not limited herein. When a specific structure of the blocking part Tis disposed, the blocking part T may be disposed as a continuous or local structure, or the blocking part T may be disposed as a discrete point shape or a discrete line shape.

As shown in FIG. 1, in some embodiments of this application, the power module may further include a second metal-clad substrate 14 disposed opposite to the first metal-clad substrate 11, and an interconnection column 15 located between the first metal-clad substrate 11 and the second metal-clad substrate 14. The chip 12 is located between the first metal-clad substrate 11 and the interconnection column 15.

Similar to the first metal-clad substrate 11, the second metal-clad substrate 14 may include: a second substrate 141, a third metal layer 142 located on a side that is of the second substrate 141 and that faces the chip 12, and a fourth metal layer 143 located on a side that is of the second substrate 141 and that is away from the chip 12. The third metal layer 142 and the fourth metal layer 143 are disposed on two sides of the second substrate 141, so that the second metal-clad substrate 14 has good heat dissipation performance, and the chip 12 can dissipate heat by using the second metal-clad substrate 14. A material of the second substrate 141 may be ceramic, and materials of the third metal layer 142 and the fourth metal layer 143 may be copper. Certainly, the second substrate 141, the third metal layer 142, and the fourth metal layer 143 may alternatively use other materials. This is not limited herein. In a specific implementation, the second metal-clad substrate 14 may be direct bond copper (DBC), active metal brazed copper (AMB, for example, Al₂O₃-AMB, Si₃N₄-AMB, or AlN-AMB), an insulated metal substrate (IMS), or the like. This is not limited herein.

The interconnection column 15 is disposed between the chip 12 and the second metal-clad substrate 14. The interconnection column 15 has good conductivity and thermal conductivity. For example, the interconnection column 15 may be made of metal, alloy, or a composite material. The interconnection column 15 may perform functions of mechanical connection, electrical connection, and heat conduction, so that the chip 12 may be electrically connected to the second metal-clad substrate 14, and the chip 12 can dissipate heat by using the second metal-clad substrate 14. In this way, metal-clad substrates are disposed on two sides of the chip 12, so that heat generated inside the power module can be discharged from a direction of the first metal-clad substrate 11 and a direction of the second metal-clad substrate 14, thereby improving heat dissipation performance of the power module.

In a specific implementation, second solder 16 may be disposed between the chip 12 and the interconnection column 15, and third solder 17 may be disposed between the interconnection column 15 and the second metal-clad substrate 14, to implement an electrical connection between the chip 12 and the interconnection column 15, and implement an electrical connection between the interconnection column 15 and the second metal-clad substrate 14. In a specific implementation, a material that is not wetted with the second solder 16 may be disposed on a surface that is of the chip 12 and that corresponds to a periphery of the interconnection column 15, to define a position of the second solder 16. In this way, when the chip 12 is welded to the interconnection column 15, the second solder 16 can be prevented from spreading to the periphery, and the second solder 16 is prevented from affecting performance of the chip 12. In a specific implementation, a groove may be disposed at the third metal layer 142 to form a line at the third metal layer 142. If wiring space of the third metal layer 142 is large, a distance between the interconnection column 15 and a surrounding groove may be long, and the third solder 17 does not overflow into an edge of the groove, and does not affect stress and a line layout of the third metal layer 142. If the wiring space of the third metal layer 142 is small, the distance between the interconnection column 15 and the surrounding groove may be close, and a blocking part may alternatively be disposed between the interconnection column 15 and the groove of the third metal layer 142, to prevent the third solder 17 from overflowing into an edge of the groove adjacent to the interconnection column 15. In this embodiment of this application, for a manner of disposing the blocking part at the third metal layer 142, refer to the blocking part at the first metal layer 112. Details are not described herein again.

In some embodiments of this application, as shown in FIG. 1, the blocking part T may include at least one recess structure t1 that is recessed towards a first direction F1. The first direction F1 is a direction in which the chip 12 points to the first metal-clad substrate 11. By disposing the recess structure t1, surface tension of the first solder 13 can be used to prevent flow of the first solder 13, and the recess structure t1 has a specific volume, and overflowed first solder 13 can flow into the recess structure t1, to buffer the overflowed first solder 13 and prevent the first solder 13 from overflowing into the edge of the groove U, to prevent the first solder 13 from overflowing into the groove U.

In a manufacturing process of the power module, the recess structure t1 may be formed by using a machining or etching method. In a specific implementation, a depth of the recess structure t1 may be 25% to 75% of the second thickness d2 of the first metal layer 112. In this way, the recess structure t1 does not penetrate the first metal layer 112, and the line layout of the first metal layer 112 is not affected. For example, the depth of the recess structure t1 may be 30%, 50%, or 70% of the second thickness d2, and may be set based on an actual requirement. A specific value of the depth of the recess structure t1 is not limited herein. Certainly, in some cases, the depth of the recess structure t1 may alternatively be less than 25% of the second thickness d2 or greater than 75% of the second thickness d2, provided that the recess structure t1 does not penetrate the first metal layer 112.

As shown in FIG. 2, in a possible implementation, the blocking part T may include one recess structure t1, and the recess structure t1 extends along a second direction (for example, a direction F2 indicated by an arrow in FIG. 2). The second direction F2 is an extension direction of a side that is of the chip 12 and that is adjacent to the blocking part T. In other words, the recess structure t1 is a strip structure extending along the second direction F2. In a specific implementation, a length of the recess structure t1 may be set to be greater than or equal to a length of the side of the corresponding chip 12, and a width of the recess structure t1 may be set based on a size of space between the corresponding chip 12 and the groove U.

FIG. 3 is another schematic diagram of a top-view structure of the power module shown in FIG. 1. As shown in FIG. 3, in another possible implementation, the blocking part T may include a plurality of recess structures t1. The plurality of recess structures t1 in the blocking part T are arranged in at least one row, an arrangement direction of the recess structures t1 is a second direction (for example, a direction F2 indicated by an arrow in FIG. 3), and the second direction F2 is an extension direction of a side that is of the chip 12 and that is adjacent to the blocking part T. In other words, the blocking part T is a strip structure formed by arranging the plurality of recess structures t1. In a specific implementation, a total length of the plurality of recess structures t1 in the blocking part T may be set to be greater than or equal to a length of the side of the corresponding chip 12, and a quantity of the recess structures t1 may be set based on a length required by the blocking part T. A width of the recess structure t1 may be set based on a size of space between the corresponding chip 12 and the groove U. In actual application, a gap between adjacent recess structures t1 may be set to be small, to prevent the first solder 13 from overflowing through the gap between adjacent recess structures t1. In FIG. 3, an example in which a shape of the recess structure t1 is circular is used for illustration. When the recess structure t1 is disposed, the recess structure t1 may alternatively be in another shape. For example, the recess structure t1 may alternatively be square, oval, or the like. The shape of the recess structure t1 is not limited herein.

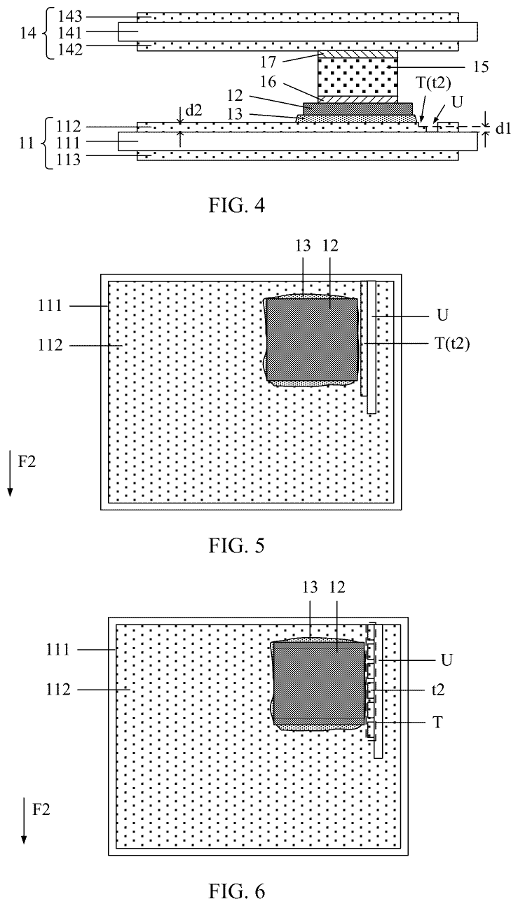

FIG. 4 is another schematic diagram of a cross-sectional structure of a power module according to an embodiment of this application. As shown in FIG. 4, in some other embodiments of this application, the blocking part T may include at least one step-shaped structure t2, and each step-shaped structure t2 includes at least one step. In FIG. 4, an example in which the step-shaped structure t2 includes one step is used for illustration. In a specific implementation, the step-shaped structure t2 may alternatively include two, three, or more steps. This is not limited herein. The step-shaped structure t2 is disposed, steps in the step-shaped structure t2 have a height difference, and a flow path of the first solder 13 can be extended. The surface tension of the first solder 13 can be utilized, so that the first solder 13 flows to an edge of the step-shaped structure t2 and stops, and the first solder 13 is prevented from overflowing into the edge of the groove U, to prevent the first solder 13 from flowing into the groove U.

In a manufacturing process of the power module, the step-shaped structure t2 may be formed by using a machining or etching method. In a specific implementation, a thickness of the step-shaped structure t2 may be 25% to 75% of the second thickness d2 of the first metal layer 112. In this way, the step-shaped structure t2 does not penetrate the first metal layer 112, and the line layout of the first metal layer 112 is not affected. For example, the thickness of the step-shaped structure t2 may be 30%, 50%, or 70% of the second thickness d2, and may be set according to an actual requirement. A specific value of the thickness of the step-shaped structure t2 is not limited herein. Certainly, in some cases, the thickness of the step-shaped structure t2 may be less than 25% of the second thickness d2 or greater than 75% of the second thickness d2, provided that the thickness of the step-shaped structure t2 does not penetrate the first metal layer 112.

FIG. 5 is a schematic diagram of a top-view structure of the power module shown in FIG. 4. As shown in FIG. 5, in a possible implementation, the blocking part T may include one step-shaped structure t2. The step-shaped structure t2 extends along a second direction (for example, a direction F2 indicated by an arrow in FIG. 5). The second direction F2 is an extension direction of a side that is of the chip 12 and that is adjacent to the blocking part T. In other words, the step-shaped structure t2 is a strip structure extending along the second direction F2. In a specific implementation, a length of the step-shaped structure t2 may be set to be greater than or equal to a length of the side of the corresponding chip 12, and a width of the step-shaped structure t2 may be set based on a size of space between the corresponding chip 12 and the groove U.

FIG. 6 is another schematic diagram of a top-view structure of the power module shown in FIG. 4. As shown in FIG. 6, in another possible implementation, the blocking part T may include a plurality of step-shaped structures t2. The plurality of step-shaped structures t2 in the blocking part T are arranged in at least one row, an arrangement direction of the step-shaped structure t2 is a second direction (for example, a direction F2 indicated by an arrow in FIG. 3), and the second direction F2 is an extension direction of a side that is of the chip 12 and that is adjacent to the blocking part T. In other words, the blocking part Tis a strip structure formed by arranging the plurality of step-shaped structures t2. In a specific implementation, a total length of the plurality of step-shaped structures t2 in the blocking part T may be set to be greater than or equal to a length of the side of the corresponding chip 12, and a quantity of step-shaped structures t2 may be set based on a length required by the blocking part T. A width of the step-shaped structure t2 may be set based on a size of space between the corresponding chip 12 and the groove U. In actual application, a gap between adjacent step-shaped structures t2 may be set to be small, to prevent the first solder 13 from overflowing through the gap between the adjacent step-shaped structures t2.

Based on a same technical concept, an embodiment of this application further provides a vehicle-mounted power circuit. The vehicle-mounted power circuit may include any one of the foregoing power modules and a circuit board. The circuit board is electrically connected to the power module. The vehicle-mounted power circuit is located in a vehicle-mounted charger or a vehicle-mounted inverter, and is configured to provide a power conversion function for an electric vehicle. In the foregoing power module, a blocking part is disposed at a first metal layer, to prevent first solder from overflowing into a gap between a chip and an edge of a groove. This can further prevent the first metal layer from being separated due to stress concentration on the edge of the groove, and improve reliability of the power module. Therefore, reliability of the vehicle-mounted power circuit including the power module is also high. A problem-resolving principle of the vehicle-mounted power circuit is similar to that of the foregoing power module. Therefore, for implementation of the vehicle-mounted power circuit, refer to the implementation of the foregoing power module. Repeated parts are not described again.

Although some embodiments of this application have been described, persons skilled in the art can make changes and modifications to these embodiments once they learn the basic inventive concept. Therefore, the following claims are intended to be construed as to cover the preferred embodiments and all changes and modifications falling within the scope of this application.

Clearly, persons skilled in the art can make various modifications and variations to embodiments of this application without departing from the spirit and scope of embodiments of this application. This application is intended to cover these modifications and variations provided that they fall within the scope of protection defined by the following claims and their equivalent technologies.

What is claimed is:

1. A power module, comprising:
a first metal-clad substrate;
a chip located on a side of the first metal-clad substrate; and
first solder located between the first metal-clad substrate and the chip, wherein:
a first metal layer is disposed on a surface of the first metal-clad substrate, wherein the surface faces the chip;
the first metal layer comprises a groove that penetrates the first metal layer in a thickness direction, wherein the first metal layer further comprises a blocking part;
a first thickness of the first metal layer is less than a second thickness, the first thickness comprises a thickness of at least a part of an area in the blocking part, and the second thickness comprises a thickness of the first metal layer in an area other than the groove and the blocking part; and
the blocking part is located between the chip and the groove adjacent to the blocking part, wherein the blocking part is configured to prevent the first solder from overflowing into the groove when the chip is welded to the first metal-clad substrate with the first solder.

2. The power module according to claim 1, the blocking part comprising:
at least one recess structure that is recessed towards a first direction, wherein the first direction is a direction in which the chip points to the first metal-clad substrate.

3. The power module according to claim 2, the blocking part comprising:
one recess structure,
wherein the one recess structure extends along a second direction, and
wherein the second direction is an extension direction of a side of the chip, and wherein the side of the chip is adjacent to the blocking part.

4. The power module according to claim 2, the blocking part comprising:
a plurality of recess structures,
wherein the plurality of recess structures in the blocking part are arranged in at least one row,
wherein an arrangement direction of the plurality of recess structures is a second direction, and
wherein the second direction is an extension direction of a side of the chip, and wherein the side of the chip is adjacent to the blocking part.

5. The power module according to claim 2, wherein a depth of the at least one recess structure comprises 25% to 75% of the second thickness of the first metal layer.

6. The power module according to claim 1, wherein the blocking part comprises at least one step-shaped structure, and
wherein each step-shaped structure comprises at least one step.

7. The power module according to claim 6, wherein the blocking part comprises one step-shaped structure, the at least one step-shaped structure extends along a second direction, and the second direction is an extension direction of a side of the chip, and wherein the side of the chip is adjacent to the blocking part.

8. The power module according to claim 6, the blocking part comprising:
a plurality of step-shaped structures,
wherein the plurality of step-shaped structures in the blocking part are arranged in at least one row,
wherein an arrangement direction of the step-shaped structures is a second direction, and
wherein the second direction is an extension direction of a side of the chip, and wherein the side of the chip is adjacent to the blocking part.

9. The power module according to claim 1, further comprising:
a second metal-clad substrate disposed opposite to the first metal-clad substrate; and
an interconnection column located between the first metal-clad substrate and the second metal-clad substrate,
wherein the chip is located between the first metal-clad substrate and the interconnection column;
wherein second solder is disposed between the chip and the interconnection column; and
wherein third solder is disposed between the interconnection column and the second metal-clad substrate.

10. A vehicle-mounted power circuit, comprising:
a power module,
wherein the power module comprises:
a first metal-clad substrate;
a chip located on a side of the first metal-clad substrate; and
first solder located between the first metal-clad substrate and the chip, wherein:
a first metal layer is disposed on a surface of the first metal-clad substrate, wherein the surface faces the chip;
the first metal layer comprises a groove that penetrates the first metal layer in a thickness direction, wherein the first metal layer further comprises a blocking part;
a first thickness of the first metal layer is less than a second thickness, the first thickness comprises a thickness of at least a part of an area in the blocking part, and the second thickness comprises a thickness of the first metal layer in an area other than the groove and the blocking part; and
the blocking part is located between the chip and the groove adjacent to the blocking part, wherein the blocking part is configured to prevent the first solder from overflowing into the groove when the chip is welded to the first metal-clad substrate with the first solder; and
a circuit board, wherein:
the circuit board is electrically connected to the power module; and
the vehicle-mounted power circuit is located in a vehicle-mounted charger or a vehicle-mounted inverter, and
the vehicle-mounted power circuit is configured to provide a power conversion function for an electric vehicle.

11. The vehicle-mounted power circuit according to claim 10, the blocking part comprising:
at least one recess structure that is recessed towards a first direction, wherein the first direction is a direction in which the chip points to the first metal-clad substrate.

12. The vehicle-mounted power circuit according to claim 11, the blocking part comprising:
one recess structure;
wherein the one recess structure extends along a second direction; and
wherein the second direction is an extension direction of a side of the chip, and wherein the side of the chip is adjacent to the blocking part.

13. The vehicle-mounted power circuit according to claim 11, the blocking part comprising:
a plurality of recess structures;
wherein the plurality of recess structures in the blocking part are arranged in at least one row,
wherein an arrangement direction of the plurality of recess structures is a second direction, and
wherein the second direction is an extension direction of a side of the chip, and wherein the side of the chip is adjacent to the blocking part.

14. The vehicle-mounted power circuit according to claim 11, wherein a depth of the at least one recess structure comprises 25% to 75% of the second thickness of the first metal layer.

15. The vehicle-mounted power circuit according to claim 10, wherein the blocking part comprises at least one step-shaped structure, and
wherein each step-shaped structure comprises at least one step.

16. The vehicle-mounted power circuit according to claim 15, wherein the blocking part comprises one step-shaped structure, the at least one step-shaped structure extends along a second direction, and the second direction is an extension direction of a side of the chip, and wherein the side of the chip is adjacent to the blocking part.

17. The vehicle-mounted power circuit according to claim 15, the blocking part comprising:
a plurality of step-shaped structures;
wherein the plurality of step-shaped structures in the blocking part are arranged in at least one row,
wherein an arrangement direction of the step-shaped structures is a second direction, and
wherein the second direction is an extension direction of a side of the chip, and wherein the side of the chip is adjacent to the blocking part.

18. The vehicle-mounted power circuit according to claim 10, further comprising:
a second metal-clad substrate disposed opposite to the first metal-clad substrate; and
an interconnection column located between the first metal-clad substrate and the second metal-clad substrate,
wherein the chip is located between the first metal-clad substrate and the interconnection column;
wherein second solder is disposed between the chip and the interconnection column; and
wherein third solder is disposed between the interconnection column and the second metal-clad substrate.
